(19) United States
(12) Patent Application Publication
(10) Pub. No.: US 2025/0273699 A1
(43) Pub. Date: Aug. 28, 2025

(54) HYDROPHILIC FUEL CELL BIPOLAR PLATES

(71) Applicant: GM GLOBAL TECHNOLOGY OPERATIONS LLC, Detroit, MI (US)

(72) Inventors: Mary GILLIAM, Farmington Hills, MI (US); Anthony Santamaria, Birmingham, MI (US)

(21) Appl. No.: 18/587,121

(22) Filed: Feb. 26, 2024

(51) Int. Cl. H01M 8/0228; H01M 8/0247; H05H 1/24

(52) U.S. Cl. CPC H01M 8/0228; H01M 8/0247; H05H 1/2437

(57) ABSTRACT

A system for modifying one or more surfaces of a bipolar plate for a fuel cell includes a bipolar plate having a first surface and a second surface opposing the first surface, and a plasma generator configured to generate plasma from a source gas including at least one non-film-forming gas for contacting the first surface of the bipolar plate to modify at least a portion of the first surface into a hydrophilic surface to attract water and/or spread water across the first surface of the bipolar plate. Other example systems, processes for modifying one or more surfaces of fuel cell bipolar plates, and fuel cell bipolar plates are also disclosed.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to hydrophilic fuel cell bipolar plates, and more particularly to modifying surfaces of fuel cell bipolar plates into hydrophilic surface.

Hydrogen fuel cells are electro-chemical devices used in a variety of applications, such as the automotive industry. A hydrogen fuel cell generally includes an anode and a cathode with an electrolyte between the anode and the cathode. In the hydrogen fuel cell, the anode receives hydrogen (e.g., hydrogen-rich gas, pure hydrogen, etc.) and the cathode receives oxygen (e.g., in air, etc.). The hydrogen is dissociated in the anode to generate protons which pass through the electrolyte to the cathode and react with the oxygen in the cathode to generate water.

In some examples, a group of fuel cells may be combined to form a stack for powering one or more loads, such as loads in a vehicle. In such examples, the stack includes one or more bipolar plates for isolating individual fuel cells. The bipolar plates are electrically and thermally conductivity and resistant to corrosion. The plates are typically made of stamped metal or molded graphite and include features, such as channels and land surfaces to facilitate reactant delivery and byproduct (e.g., water and heat) removal.

### SUMMARY

A system for modifying one or more surfaces of a bipolar plate for a fuel cell includes a bipolar plate having a first surface and a second surface opposing the first surface, and a plasma generator configured to generate plasma from a source gas including at least one non-film-forming gas for contacting the first surface of the bipolar plate to modify at least a portion of the first surface into a hydrophilic surface to attract water and/or spread water across the first surface of the bipolar plate.

In other features, a chemical precursor is applied to the first surface of the bipolar plate prior to the plasma contacting the first surface of the bipolar plate to graft hydrophilic moieties onto the first surface.

In other features, the chemical precursor includes at least one functional group containing hydroxyl, carbon-oxygen bonds, or nitrogen-containing groups.

In other features, the plasma generator is configured to discharge the chemical precursor towards the first surface of the bipolar plate.

In other features, the system further includes a sprayer configured to discharge the chemical precursor towards the first surface of the bipolar plate.

In other features, the chemical precursor forms a hydrophilic film on the first surface, wherein the hydrophilic film includes a thickness of 500 nm or less.

In other features, the plasma generator includes a plurality of atmospheric pressure plasma jets directed to the first surface, and the plurality of atmospheric pressure plasma jets are configured to generate the plasma for contacting the first surface of the bipolar plate.

In other features, the plurality of atmospheric pressure plasma jets are a first plurality of atmospheric pressure plasma jets, the system further includes a second plurality of atmospheric pressure plasma jets directed to the second surface of the bipolar plate, and the second plurality of atmospheric pressure plasma jets are configured to generate plasma for contacting the second surface of the bipolar plate to modify at least a portion of the second surface into a hydrophilic surface to attract water and/or spread water across the second surface of the bipolar plate.

In other features, the system further includes a dielectric layer arranged adjacent to the first surface of the bipolar plate. The dielectric layer and the first surface of the bipolar plate define a gap therebetween. The plasma generator is configured to generate the plasma in the gap when an AC voltage is applied to the bipolar plate.

In other features, the bipolar plate is a first bipolar plate and the gap is a first gap, and the system further includes a second bipolar plate. The dielectric layer is arranged between the first bipolar plate and the second bipolar plate, and the dielectric layer and the second bipolar plate define a second gap therebetween. The plasma generator is configured to generate the plasma in the first gap and the second gap when the AC voltage is applied to the first bipolar plate and the second bipolar plate.

In other features, the dielectric layer is a first dielectric layer and the gap is a first gap, and the system further includes a second dielectric layer arranged adjacent to the second surface of the bipolar plate. The second dielectric layer and the second surface of the bipolar plate define a second gap therebetween, and the plasma generator is configured to generate the plasma in the first gap and the second gap when the AC voltage is applied to the bipolar plate.

A process for modifying one or more surfaces of a bipolar plate for a fuel cell includes providing a bipolar plate having a first surface and a second surface opposing the first surface, and generating plasma from a source gas including at least one non-film-forming gas for contacting the first surface of the bipolar plate to modify at least a portion of the first surface into a hydrophilic surface to attract water and/or spread water across the first surface of the bipolar plate.

In other features, the process further includes applying a chemical precursor to the first surface of the bipolar plate to graft hydrophilic moieties onto the first surface.

In other features, the chemical precursor includes at least one functional group containing hydroxyl, carbon-oxygen bonds, or nitrogen-containing groups.

In other features, the chemical precursor forms a hydrophilic film on the first surface.

In other features, the hydrophilic film includes a thickness of 500 nm or less.

In other features, the process further includes arranging a dielectric layer adjacent to the first surface of the bipolar plate.

In other features, the dielectric layer and the first surface of the bipolar plate define a gap therebetween, and generating the plasma includes generating the plasma in the gap when an AC voltage is applied to the bipolar plate.

In other features, the bipolar plate is a first bipolar plate and the gap is a first gap, and the process further includes providing a second bipolar plate. The dielectric layer is arranged between the first bipolar plate and the second bipolar plate, and the dielectric layer and the second bipolar plate define a second gap therebetween.

In other features, generating the plasma includes generating the plasma in the first gap and the second gap when the AC voltage is applied to the bipolar plate.

In other features, the dielectric layer is a first dielectric layer and the gap is a first gap, and the process further includes arranging a second dielectric layer adjacent to the second surface of the bipolar plate. The second dielectric layer and the second surface of the bipolar plate define a second gap therebetween.

In other features, generating the plasma includes generating the plasma in the first gap and the second gap when the AC voltage is applied to the bipolar plate.

A bipolar plate for a fuel cell includes a first surface, a second surface opposing the first surface, and a hydrophilic film grafted onto the first surface to attract water and/or spread water across the first surface of the bipolar plate.

In other features, the hydrophilic film has a thickness of 500 nm or less.

In other features, the thickness is less than 100 nm.

In other features, the hydrophilic film includes at least one functional group containing hydroxyl, carbon-oxygen bonds, or nitrogen-containing groups.

In other features, the hydrophilic film is a first hydrophilic film, and the bipolar plate further includes a second hydrophilic film grafted onto the second surface to attract water and/or spread water across the second surface of the bipolar plate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a diagram of an example system including atmospheric pressure plasma jets for modifying a surface of a fuel cell bipolar plate, according to the present disclosure;

FIG. 2 is a diagram of an example system including two sets of atmospheric pressure plasma jets for modifying opposing surfaces of a fuel cell bipolar plate, according to the present disclosure;

FIG. 3 is a diagram of an example system including atmospheric pressure plasma jets and a chemical precursor sprayer for modifying a surface of a fuel cell bipolar plate, according to the present disclosure;

FIG. 4 is a diagram of an example atmospheric pressure plasma jet with a chemical precursor sprayer, according to the present disclosure;

FIG. 5 is a diagram of an example system including a dielectric barrier plasma discharge assembly for modifying a surface of a fuel cell bipolar plate, according to the present disclosure;

FIG. 6 is a diagram of an example system including a dielectric barrier plasma discharge assembly for modifying a surface of two fuel cell bipolar plates, according to the present disclosure;

FIG. 7 is a diagram of an example system including a dielectric barrier plasma discharge assembly for modifying surfaces of fuel cell bipolar plates, according to the present disclosure;

FIG. 8 is a diagram of an example fuel cell stack including multiple bipolar plates according to the present disclosure; and

FIG. 9 is a graph plotting a wicking length ratio over time according to the present disclosure.

In the drawings, reference numbers may be reused to identify similar and/or identical elements.

### DETAILED DESCRIPTION

Bipolar plates separate fuel cells in a stack. The bipolar plates include features, such as channels and land surfaces to facilitate reactant delivery for producing electrical energy and byproduct removal produced during the production of electrical energy. In such examples, the channels and/or the land surfaces may be arranged to collect and facilitate the removal of water and/or heat (e.g., via a liquid) from the fuel cell stack. As such, it is desirable for the channels and/or the land surfaces of the bipolar plates to have hydrophilic characteristics to help attract and remove water from the fuel cell stack. However, newly formed bipolar plates are generally hydrophobic. In some instances, the bipolar plates may become hydrophilic over time due to, for example, in-situ washing effects. For example, it may take 100s of hours (e.g., more than 200 hrs) for a bipolar plate to become hydrophilic before a stack can run stable at lower anode stoichiometry. This break-in process for bipolar plates requires a significant amount of time and hydrogen consumption.

The systems and methods according to the present disclosure provide solutions for modifying fuel cell bipolar plates to form hydrophilic moieties or functional groups on surfaces of the plates for managing water and other liquid produced and/or present in fuel cells. In various embodiments, the hydrophilic surfaces may be created using plasma surface treatments with non-depositing gases applied to the surfaces of the bipolar plates, as further explained below. In some examples, an optional chemical precursor may be added to permanently graft to or to form a thin film of hydrophilic compounds and functional groups on the surfaces of the bipolar plates, as further explained below. With such plasma surface treatments, surfaces of bipolar plates may be quickly modified to create hydrophilic surfaces having wettability characteristics comparable to a bipolar plate that has been broken in after about 200 or more hours and without requiring hydrogen. As such, by utilizing the solutions herein to create bipolar plate with hydrophilic surfaces, the time, hydrogen consumption, and costs associated with breaking in a conventional bipolar plate are significantly reduced and sometimes eliminated.

As further explained herein, the systems and methods herein generally include a fuel cell bipolar plate having opposing surfaces, and a plasma generator. In such examples, one or both surfaces of the bipolar plate may include channels and/or land surfaces to facilitate reactant delivery for producing electrical energy and byproduct removal produced during the production of electrical energy. Additionally, the plasma generator is arranged to generate and/or discharge plasma for contacting at least one of surfaces of the bipolar plate to modify at least a portion (e.g., one or more channels and/or land surfaces) of the surface into a hydrophilic surface to attract water and/or spread water across the first surface of the bipolar plate.

In various embodiments, the bipolar plates herein may be formed of any suitable material. For example, the bipolar plates may be electrically and thermally conductivity and resistant to corrosion. In such examples, any one of the bipolar plates may be formed of stamped metal or molded graphite. In some examples, bipolar plates formed of metal may include protective coatings, such as carbon to improve electrical conductivity and/or to prevent corrosion.

In various embodiments, the plasma generators herein may be any suitable devices and/or configurations for providing plasma surface treatments to the bipolar plates. For example, and as further explained herein, the plasma generators may include one or more sets of atmospheric pressure plasma jets, an AC dielectric barrier discharge (DBD) configuration, etc.

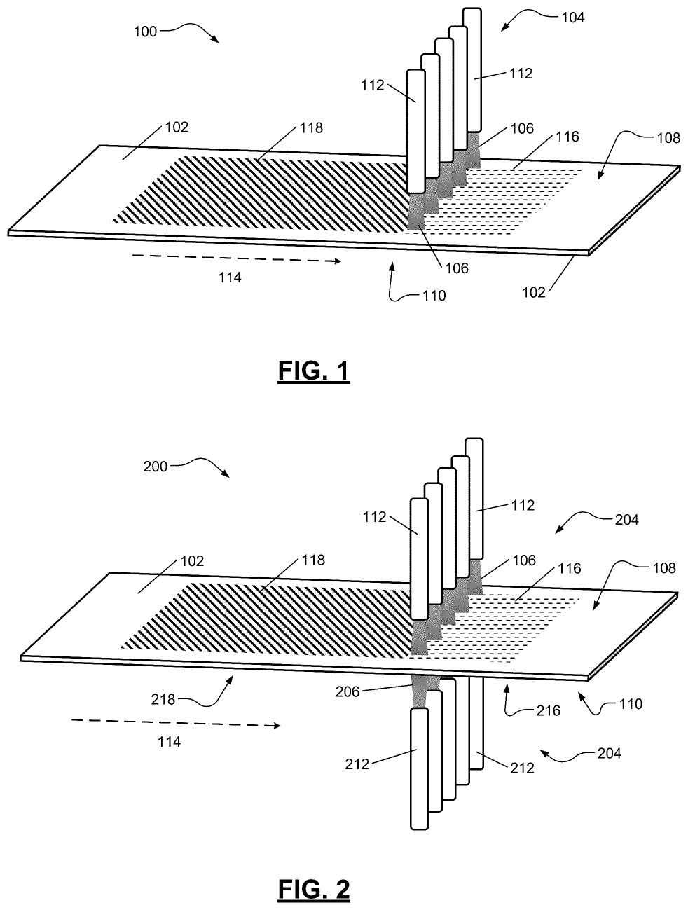

Referring now to FIG. 1, a diagram of an example system 100 is presented for modifying a surface of a bipolar plate. The system 100 of FIG. 1 and/or any of the other example systems and methods herein may be applicable in the manufacturing of bipolar plates of fuel cells for vehicle applications and/or any other suitable applications including fuel cells for powering various aspects associated therewith.

As shown in FIG. 1, the system 100 generally includes a bipolar plate 102 and a plasma generator 104 for generating and discharging a stream of plasma 106 for contacting the bipolar plate 102. The bipolar plate 102 includes opposing top and bottom surfaces 108, 110 having channels and/or land surfaces to facilitate reactant delivery for producing electrical energy and byproduct removal produced during the production of electrical energy. In such examples, the plasma 106 effectively modifies at least a portion of the top surface 108 of the bipolar plate 102 into a hydrophilic surface to attract water and/or spread water across the surface 108. In doing so, the plasma 106 causes hydrophilic moieties or functional groups to form on the surface 108 for managing water produced in fuel cells.

In various embodiments, the generation and discharge of plasma may be accomplished with different configurations and/or devices. For example, in FIG. 1, the plasma generator 104 includes atmospheric pressure plasma jets 112 directed to the top surface 108 of the bipolar plate 102. The plasma jets 112 generate and discharge the stream of plasma 106 for contacting the top surface 108. For example, each plasma jet 112 may be a conventional atmospheric pressure plasma jet including a working or source gas inlet, electrodes (e.g., a cylindrical shaped cathode, an outer glass/dielectric shield wrapped by an anode, etc.), and outlet for discharging the stream of plasma 106. In such examples, a high AC voltage is applied to the electrodes to generate the plasma 106. In various embodiments, the plasma 106 may be generated from a source gas (e.g., introduced into the gas inlet). For example, the source gas may include at least one non-film-forming gas. As examples, the source gas may include dry air, nitrogen, argon, helium, neon, carbon dioxide, hydrogen and/or a mixture thereof.

In the example of FIG. 1, the atmospheric pressure plasma jets 112 are arranged as a linear array of five jets. In other examples, the plasma generator 104 of FIG. 1 may include more or less plasma jets (e.g., three jets, four jets, six jets, eight jets, etc.) depending on various parameters, such as the size of the bipolar plate 102, the characteristics of each jet (e.g., the jet head size, the jet head orientation, etc.), etc. Additionally, while the plasma jets 112 are arranged in a linear array in FIG. 1, it should be appreciated that the plasma jets 112 may be arranged in another suitable manner (e.g., an angular array, individually arranged, etc.) if desired.

In various embodiments, each atmospheric pressure plasma jet 112 of FIG. 1 may include various characteristics. For example, in FIG. 1, each plasma jet 112 may include a jet head in which the stream of plasma 106 is discharged. The jet head for each plasma jet 112 may have a desirable size to reduce treatment time and avoid localized flexing due to temperature gradients. Additionally, the orientation of each jet head may be such to better treat features, such as channels and feed regions and/or to increase/decrease the area treated by each plasma jet 112. In various embodiments, the jet head of each plasma jet 112 may be directed to the surface of the bipolar plate 102 at an acute angle.

In the example of FIG. 1, the atmospheric pressure plasma jets 112 are fixed. In such examples, the bipolar plate 102 may be moved relative to the plasma jets 112 along a scan direction as indicated by a dashed arrow 114. In various embodiments, the bipolar plate 102 may be moved with one or more robotic arms, a conveyor, and/or any other suitable mechanism for moving components. In other examples, the bipolar plate 102 may remain substantially fixed or stationary and the plasma jets 112 may move relative to the bipolar plate 102 (e.g., move along the scan direction). In either case, the plasma jets 112 treat a portion of the top surface 108 as the bipolar plate 102 (or the plasma jets 112) moves. In FIG. 1, the treated portion is represented by a treated region 116 (e.g., cross hatching with horizontal extending dashes) and the untreated portion is represented by an untreated region 118 (e.g., cross hatching with diagonal extending lines).

As shown in FIG. 1, the system 100 is arranged to perform a single sided plasma surface treatment of the bipolar plate 102. In other words, the plasma jets 112 of FIG. 1 are all arranged on one side of the bipolar plate 102 and directed to the top surface 108 of the bipolar plate 102 for modifying only the top surface 108. In other examples, the system 100 and/or other systems herein may be arranged to perform a double-sided plasma surface treatment of the bipolar plate 102. In such examples, the system 100 may include two sets of plasma jets, one directed to the top surface 108 of the bipolar plate 102 and one directed to the bottom surface 110 of the bipolar plate 102 for modifying both surfaces 108, 110.

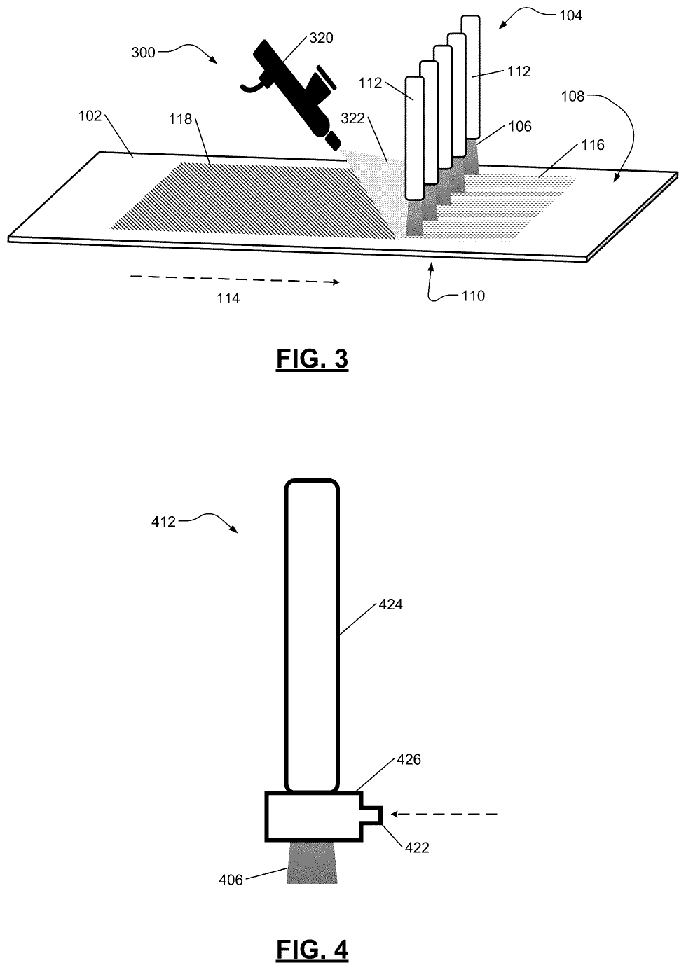

For example, FIG. 2 depicts a diagram of another example system 200 for modifying surfaces of the bipolar plate 102. The system 200 of FIG. 2 is substantially similar to the system 100 of FIG. 1 but includes an additional set of plasma jets. Specifically, the system 200 of FIG. 2 includes the bipolar plate 102 of FIG. 1 and a plasma generator 204 having the atmospheric pressure plasma jets 112 of FIG. 1 directed to the top surface 108 of the bipolar plate 102 and atmospheric pressure plasma jets 212 directed to the bottom surface 110 of the bipolar plate 102. In the example of FIG. 2, each plasma jet 112 generates and discharges a stream of plasma 106 for contacting the top surface 108 and each plasma jet 212 generates and discharges a stream of plasma 206 for contacting the bottom surface 110. In such examples, both surfaces 108, 110 (or portions thereof) are modified into hydrophilic surfaces to attract water and/or spread water across the second surface of the bipolar plate.

In the example of FIG. 2, the atmospheric pressure plasma jets 212 may be similar to the plasma jets 112. For example, the plasma jets 212 may be arranged as a linear array of five jets as shown. Alternatively, the plasma jets 212 may include more or less plasma jets, arranged in a different manner, etc. as explained above relative to the plasma jets 112 of FIG. 1. Additionally, the plasma jets 112, 212 may be stationary while the bipolar plate 102 is moved relative to the plasma jets 112, 212 along the scan direction as indicated by the dashed arrow 114 to create treated regions 116, 216 from untreated regions 118, 218 on the top and bottom surfaces 108, 110 of the bipolar plate 102, as explained above relative to the system 100 of FIG. 1. Alternatively, the plasma jets 112, 212 may be moved relative to the bipolar plate 102 if desired.

In various embodiments, any one of the systems herein may introduce a stream of one or more chemical precursors to the plasma process to graft hydrophilic functional groups to the surface or create a hydrophilic thin layer. In such examples, adding the chemical precursors to functionalize the surface may provide for a longer storage time. The chemical precursors may be delivered in any suitable form and through a variety of manners. For example, the precursor(s) may be delivered in gas, vapor, or aerosol form. Additionally, and as further explained herein, the chemical precursor(s) may be directed into the plasma, onto surface(s) of a bipolar plate being treated prior to the plasma contacting the surface(s), etc. In such examples, the chemical precursor(s) may be applied via one or more sprayers, injection ports on atmospheric pressure plasma jets, and/or any other suitable mechanism for delivering the chemical precursor(s).

In some examples, one or more chemical precursors may be applied to surface(s) of a bipolar plate to graft (e.g., permanently graft) hydrophilic moieties onto the surface(s). In other embodiments, the applied chemical precursor(s) may form a hydrophilic film on the surface(s). In such examples, the hydrophilic film may be thin relative to the thickness of the bipolar plate. For example, the hydrophilic film may have a thickness of 500 nm or less. In some examples, the thickness may be less than 100 nm.

In various embodiments, the chemical precursor(s) may include any suitable compound having normal melting points less than or equal to 20° C. For example, the chemical precursor(s) may include small molecules, monomers, oligomers, or polymers. In such examples, the monomers, oligomers, or polymers may consist of at least one functional group containing hydroxyl, carbon-oxygen bonds, such as ethers and carbonyl groups, or nitrogen-containing groups, such as amides, amines, and imines. For example, the hydroxyl functional groups may include water, diluted organic peroxides, and alcohols (e.g., ethanol, 1-butanol, ethylene glycol, propylene glycol, glycerol, etc.), the carbonyl functional groups may include aldehydes (e.g., acetaldehyde, etc.), ketones (e.g., acetone, acetylacetone, etc.), acrylates (e.g., hexanediol diacrylate), methacrylates (e.g., methyl methacrylate, hydroxyethyl methacrylate, etc.), and carboxylic acids (e.g., formic acid, acetic acid, etc.), and the amine functional groups may include primary, secondary, or tertiary amines (e.g., butylamine, ethylenediamine, diethylenetriamine, etc.).

For example, FIG. 3 depicts a diagram of another example system 300 for modifying surfaces of the bipolar plate 102. The system 300 of FIG. 3 is substantially similar to the system 100 of FIG. 1 but includes a sprayer for discharging a chemical precursor towards a surface of the bipolar plate 102. Specifically, the system 300 of FIG. 3 includes the bipolar plate 102 of FIG. 1, the plasma generator 104 of FIG. 1 having the atmospheric pressure plasma jets 112 for generating and discharging the plasma 106 for contacting the top surface 108 of the bipolar plate 102, and a sprayer 320. In the example of FIG. 3, the sprayer 320 may be manually or electronically controlled to discharge a stream of one or more chemical precursors 322 towards the bipolar plate 102. The chemical precursor(s) 322 may include any one or more of the example compounds referenced above.

As shown in FIG. 3, the sprayer 320 provides the stream of chemical precursor(s) 322 towards the top surface 108 of the bipolar plate 102. In other examples, the system 300 may include another sprayer to discharge a stream of one or more chemical precursors towards the bottom surface 110 of the bipolar plate 102 if the bottom surface 110 is being plasma treated (e.g., as in the system 200 of FIG. 2).

In the example of FIG. 3, the sprayer 320 applies the chemical precursor(s) 322 upstream of the atmospheric pressure plasma jets 112. For example, the sprayer 320 directs the stream of chemical precursor(s) 322 towards the top surface 108 of the bipolar plate 102 prior to the plasma 106 contacting the surface 108. In such examples, the plasma jets 112 and the sprayer 320 may remain stationary while the bipolar plate 102 is moved relative to the plasma jets 112 and the sprayer 320 along the scan direction as indicated by the dashed arrow 114 to create the treated region 116 (having a chemical precursor and plasma surface treatment) from the untreated region 118, as explained above relative to the system 100 of FIG. 1. Alternatively, the plasma jets 112 and the sprayer 320 may be moved relative to the bipolar plate 102 if desired.

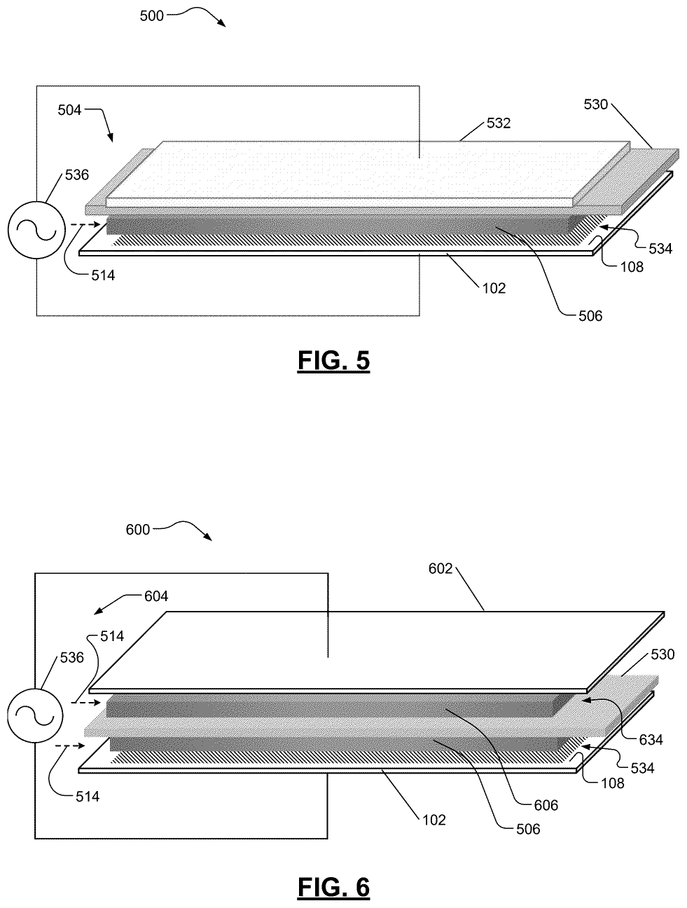

In other examples, any one of the atmospheric pressure plasma jets herein may be arranged to discharge a stream of one or more precursors towards a surface of the bipolar plate 102. For example, FIG. 4 depicts a diagram of an example atmospheric pressure plasma jet 412 that may be employed as any one of the atmospheric pressure plasma jets 112, 212 herein. As shown in FIG. 4, the plasma jet 412 includes a body 424, a chamber 426, and a port 422 for receiving a stream containing one or more precursors. In such examples, the stream may include a carrier gas (e.g., nitrogen, etc.) containing vapors or aerosols of the precursors, as explained herein. The body 424 may include conventional atmospheric pressure plasma jet components, such as a working or source gas inlet, electrodes (e.g., a cylindrical shaped cathode, an outer glass/dielectric shield wrapped by an anode, etc.), and outlet for discharging a stream of plasma 406. In the example of FIG. 4, the precursor stream mixes with the plasma 406 exiting the jet 412 inside the chamber 426 attached to a jet exit. Compounds produced in the chamber 426 may include, for example, decomposition products, ions, radicals, and products of recombination.

In various embodiments, plasma surface treatments for modifying surfaces of bipolar plates may be accomplished via other suitable mechanisms other than atmospheric pressure plasma jets. For example, in some embodiments a plasma generator may have an AC dielectric barrier discharge (DBD) configuration for providing plasma surface treatments for modifying one or more surfaces of bipolar plates. In such examples, plasma may be generated by applying an AC voltage across a gas to ionize the gas. In such examples, the AC voltage may be provided by any suitable AC generator (e.g., a high voltage AC generator). When employed, the AC DBD configuration generates plasma for contacting at least surface of one or more bipolar plates to modify at least a portion of the surface into a hydrophilic surface to attract water and/or spread water across the bipolar plate, as explained herein. Additionally, in various embodiments, one or more chemical precursors as explained herein may be introduced along with the AC DBD configuration if desired.

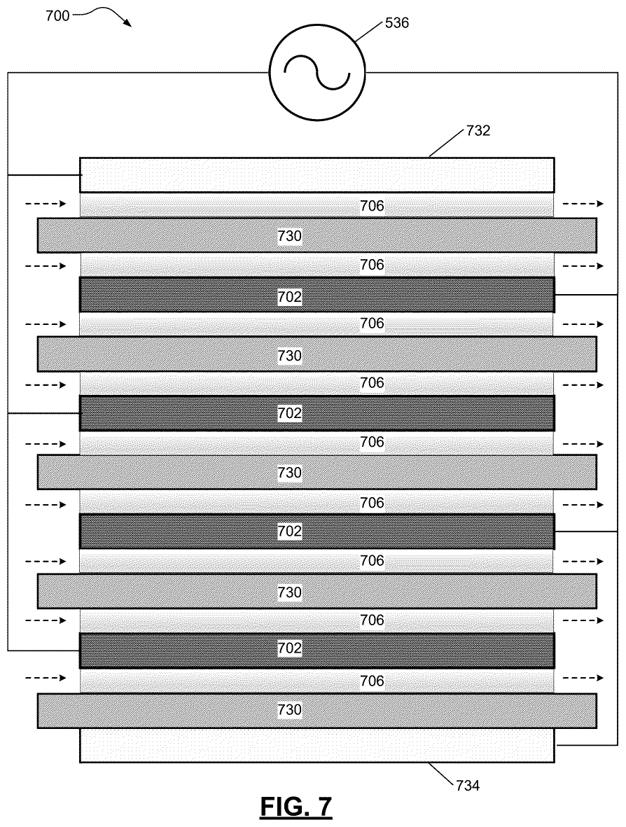

For example, FIG. 5 depicts a diagram of an example system 500 for modifying a surface of a bipolar plate using an AC DBD configuration. As shown in FIG. 5, the system 500 generally includes the bipolar plate 102 of FIG. 1 having the top surface 108 and a plasma generator 504 having an AC power generator 536. In the example of FIG. 5, the system 500 further includes a dielectric layer 530 arranged adjacent to the top surface 108 of the bipolar plate 102 and an electrode 532 arranged adjacent to the dielectric layer 530. In such examples, the dielectric layer 530 may be formed of any suitable dielectric material and positioned between the bipolar plate 102 and the electrode 532. The AC power generator 536 is electrically connected across the bipolar plate 102 and the electrode 532 as shown in FIG. 5.

In the example of FIG. 5, the plasma generator 504 is in the form of an AC DBD configuration for generating plasma 506 for contacting the top surface 108 of the bipolar plate 102. For example, and as shown in FIG. 5, the dielectric layer 530 and the top surface 108 of the bipolar plate 102 define a gap 534 therebetween. A source gas, such dry air, nitrogen, argon, helium, neon, carbon dioxide, hydrogen and/or a mixture thereof is introduced into the gap 534. In the example of FIG. 5, the source gas may flow into the gap 534 as indicated by a dashed arrow 514. In other examples, the source gas may flow into the gap 534 in another direction if desired. Then, the AC power generator 536 may be controlled to apply an AC voltage (e.g., a high AC voltage, such as 1-10 kV) across the gap 534 via the bipolar plate 102 and the electrode 532 to ionize the source gas in the gap 534 and generate the plasma 506 for contacting the top surface 108 of the bipolar plate 102.

In various embodiments, an AC DBD configuration may be employed to provide plasma surface treatments for modifying surfaces of two different bipolar plates. For example, FIG. 6 depicts a diagram of an example system 600 for modifying surfaces of two bipolar plates using an AC DBD configuration. The system 600 of FIG. 6 is similar to the system 500 of FIG. 5 but includes an additional bipolar plate that replaces the electrode 532. Specifically, the system 600 of FIG. 6 includes the bipolar plate 102 of FIG. 5 having the top surface 108, a bipolar plate 602 substantially similar to the bipolar plate 102, and a plasma generator 604 having the AC power generator 536 of FIG. 5. The bipolar plate 602 includes a bottom surface facing the top surface 108 of the bipolar plate 102. In the example of FIG. 6, the system 600 further includes the dielectric layer 530 of FIG. 5 arranged between the bipolar plates 102, 602. The AC power generator 536 is electrically connected across the bipolar plates 102, 602 as shown in FIG. 5.

Similar to the plasma generator 504 of FIG. 5, the plasma generator 604 of FIG. 6 is in the form of an AC DBD configuration for generating plasma 506, 606 for contacting the top surface 108 of the bipolar plate 102 and the bottom surface of the bipolar plate 602. For example, and as shown in FIG. 6, the dielectric layer 530 and the top surface 108 of the bipolar plate 102 define the gap 534 therebetween, and the dielectric layer 530 and the bottom surface of the bipolar plate 602 define a gap 634 therebetween. A source gas is introduced into the gaps 534, 634 (e.g., by a flow path indicated by the dashed arrows 514). Then, the AC power generator 536 may be controlled to apply an AC voltage across the gaps 534, 634 (via the bipolar plates 102, 602) to ionize the source gas in the gaps 534, 634 and generate the plasmas 506, 606 for contacting the interior facing surfaces of the bipolar plates 102, 602.

In various embodiments, an AC DBD configuration may be employed to provide a two-sided plasma surface treatment. In such examples, the AC DBD configuration may be arranged to modify multiple surfaces of multiple bipolar plates. For example, FIG. 7 depicts a diagram of an example system 700 for modifying multiple surfaces of multiple bipolar plates using an AC DBD configuration. The system 700 of FIG. 7 is similar to the systems 500, 600 of FIGS. 5-6 but includes additional bipolar plates and dielectric layers. Specifically, the system 700 of FIG. 6 includes a plasma generator having the AC power generator 536 of FIG. 5, and a multi-layer stack having multiple bipolar plates 702 (e.g., similar to the bipolar plates 102 described above), multiple dielectric layers 730 (e.g., similar to the dielectric layers 530 described above), and two electrodes 732, 734. In the example of FIG. 7, each bipolar plate 702 is arranged between two adjacent dielectric layers 730, and the electrodes 732, 734 are positioned on opposing sides of the stack. As shown, the AC power generator 536 is electrically connected to the electrodes 732, 734 and the bipolar plates 702.

In the example of FIG. 7, the system 700 includes four bipolar plates 702 and five dielectric layers 730. In other embodiments, more or less bipolar plates and dielectric layers may be employed.

Similar to the plasma generators 504, 604 of FIGS. 5-6, the plasma generator of FIG. 7 is in the form of an AC DBD configuration for generating plasma 706 for contacting opposing surfaces of each bipolar plate 702. For example, and as shown in FIG. 7, each dielectric layer 730 and each surface of the bipolar plates 702 define a gap therebetween. A source gas is introduced into each gap (e.g., by a flow path indicated by dashed arrows). Then, the AC power generator 536 may be controlled to apply an AC voltage across the gaps (via the electrodes 732, 734 and the bipolar plates 702) to ionize the source gas in the gaps and generate the plasma 706 for contacting the surfaces of the bipolar plates 702.

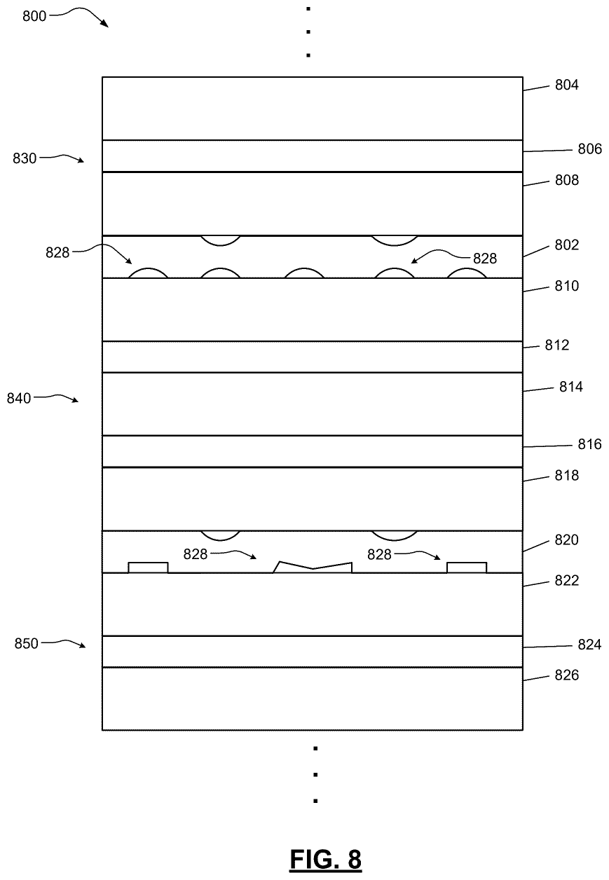

As explained herein, the bipolar plates having modified surfaces may be employed in fuel cells for vehicle applications and/or any other suitable applications. FIG. 8 depicts a diagram of an example stack 800 of multiple fuel cells 830, 840, 850 and two bipolar plates 802, 820. In the example of FIG. 8, the bipolar plates 802, 820 may be any one of the bipolar plates disclosed herein. As shown in FIG. 8, each bipolar plate 802, 820 includes channels 828 to facilitate reactant delivery and byproduct (e.g., water and heat) removal. In such examples, each channel 828 may be the same shape and size or different as shown in FIG. 8.

As shown in FIG. 8, the fuel cell 840 includes gas diffusion layers 810, 818, a polymer electrolyte membrane layer 814 between the gas diffusion layers 810, 818, one or more electrodes 812 (e.g., anode side electrodes) between the gas diffusion layer 810 and the polymer electrolyte membrane layer 814, and one or more electrodes 816 (e.g., cathode side electrodes) between the polymer electrolyte membrane layer 814 and the gas diffusion layer 818, as is conventional. The bipolar plates 802, 820 are arranged on opposing sides of the gas diffusion layers 810, 818 as shown in FIG. 8.

The fuel cells 830, 850 include similar layers as the fuel cell 840, of which only a portion are shown for clarity. For example, the fuel cell 830 is shown as including a gas diffusion layer 808 adjacent to the bipolar plate 802, one or more electrodes 806 (e.g., cathode side electrodes), and a polymer electrolyte membrane layer 804. Additionally, the fuel cell 850 is shown as including a gas diffusion layer 822 adjacent to the bipolar plate 820, one or more electrodes 824 (e.g., anode side electrodes), and a polymer electrolyte membrane layer 826.

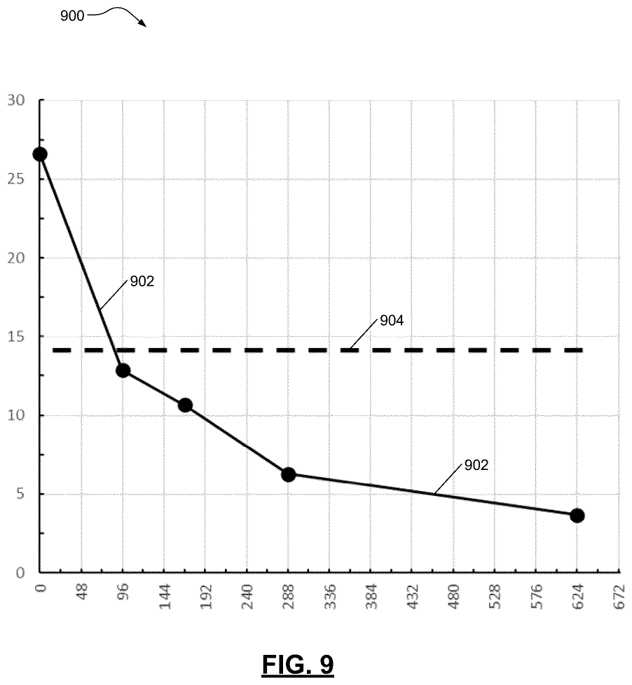

FIG. 9 depicts a graph 900 plotting a wicking length ratio over time (in hours) since plasma surface modification. In the example of FIG. 9, the wicking length ratio (represented by a line 902) is defined as a plasma treated plate wicking length divided by an untreated plate wicking length. In such examples, the wicking length represents the amount of wicking that occurs after water is dropped onto the surface. Testing has shown that untreated bipolar plates are hydrophobic and have short wicking lengths (e.g., less than about 0.5 cm). In contrast, treated bipolar plates show significant increases in hydrophilicity immediately after plasma exposure which then decays over time (depending possibly on, for example, storage, coating type, etc.) to a steady value. The treated bipolar plates still retain higher hydrophilicity after several days, weeks, etc. than the untreated bipolar plates and in some cases have the same hydrophilicity as untreated broken-in bipolar plates. For example, the graph 900 includes a dashed line 904 representing a wicking length ratio for an untreated broken-in bipolar plate. In such examples, the untreated bipolar plate has a break-in time of about 300 hours.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A system for modifying one or more surfaces of a bipolar plate for a fuel cell, the system comprising:
a bipolar plate having a first surface and a second surface opposing the first surface; and
a plasma generator configured to generate plasma from a source gas including at least one non-film-forming gas for contacting the first surface of the bipolar plate to modify at least a portion of the first surface into a hydrophilic surface to attract water and/or spread water across the first surface of the bipolar plate.

2. The system of claim 1, wherein:
a chemical precursor is applied to the first surface of the bipolar plate prior to the plasma contacting the first surface of the bipolar plate to graft hydrophilic moieties onto the first surface; and
the chemical precursor includes at least one functional group containing hydroxyl, carbon-oxygen bonds, or nitrogen-containing groups.

3. The system of claim 2, wherein:
the plasma generator is configured to discharge the chemical precursor towards the first surface of the bipolar plate; or
the system further comprises a sprayer configured to discharge the chemical precursor towards the first surface of the bipolar plate.

4. The system of claim 2, wherein the chemical precursor forms a hydrophilic film on the first surface, wherein the hydrophilic film includes a thickness of 500 nm or less.

5. The system of claim 1, wherein:
the plasma generator includes a plurality of atmospheric pressure plasma jets directed to the first surface; and
the plurality of atmospheric pressure plasma jets are configured to generate the plasma for contacting the first surface of the bipolar plate.

6. The system of claim 5, wherein:
the plurality of atmospheric pressure plasma jets are a first plurality of atmospheric pressure plasma jets;
the system further comprises a second plurality of atmospheric pressure plasma jets directed to the second surface of the bipolar plate; and
the second plurality of atmospheric pressure plasma jets are configured to generate plasma for contacting the second surface of the bipolar plate to modify at least a portion of the second surface into a hydrophilic surface to attract water and/or spread water across the second surface of the bipolar plate.

7. The system of claim 1, further comprising a dielectric layer arranged adjacent to the first surface of the bipolar plate, wherein:
the dielectric layer and the first surface of the bipolar plate define a gap therebetween; and
the plasma generator is configured to generate the plasma in the gap when an AC voltage is applied to the bipolar plate.

8. The system of claim 7, wherein:
the bipolar plate is a first bipolar plate and the gap is a first gap;
the system further comprises a second bipolar plate;
the dielectric layer is arranged between the first bipolar plate and the second bipolar plate;
the dielectric layer and the second bipolar plate define a second gap therebetween; and
the plasma generator is configured to generate the plasma in the first gap and the second gap when the AC voltage is applied to the first bipolar plate and the second bipolar plate.

9. The system of claim 7, wherein:
the dielectric layer is a first dielectric layer and the gap is a first gap;
the system further comprises a second dielectric layer arranged adjacent to the second surface of the bipolar plate;
the second dielectric layer and the second surface of the bipolar plate define a second gap therebetween; and
the plasma generator is configured to generate the plasma in the first gap and the second gap when the AC voltage is applied to the bipolar plate.

10. A process for modifying one or more surfaces of a bipolar plate for a fuel cell, the process comprising:
providing a bipolar plate having a first surface and a second surface opposing the first surface; and
generating plasma from a source gas including at least one non-film-forming gas for contacting the first surface of the bipolar plate to modify at least a portion of the first surface into a hydrophilic surface to attract water and/or spread water across the first surface of the bipolar plate.

11. The process of claim 10, further comprising applying a chemical precursor to the first surface of the bipolar plate to graft hydrophilic moieties onto the first surface, wherein the chemical precursor includes at least one functional group containing hydroxyl, carbon-oxygen bonds, or nitrogen-containing groups.

12. The process of claim 11, wherein:
the chemical precursor forms a hydrophilic film on the first surface; and
the hydrophilic film includes a thickness of 500 nm or less.

13. The process of claim 10, wherein:
the process further comprises arranging a dielectric layer adjacent to the first surface of the bipolar plate;
the dielectric layer and the first surface of the bipolar plate define a gap therebetween; and
generating the plasma includes generating the plasma in the gap when an AC voltage is applied to the bipolar plate.

14. The process of claim 13, wherein:
the bipolar plate is a first bipolar plate and the gap is a first gap;
the process further comprises providing a second bipolar plate;
the dielectric layer is arranged between the first bipolar plate and the second bipolar plate;
the dielectric layer and the second bipolar plate define a second gap therebetween; and
generating the plasma includes generating the plasma in the first gap and the second gap when the AC voltage is applied to the bipolar plate.

15. The process of claim 13, wherein:
the dielectric layer is a first dielectric layer and the gap is a first gap;
the process further comprises arranging a second dielectric layer adjacent to the second surface of the bipolar plate;
the second dielectric layer and the second surface of the bipolar plate define a second gap therebetween; and
generating the plasma includes generating the plasma in the first gap and the second gap when the AC voltage is applied to the bipolar plate.

16. A bipolar plate for a fuel cell, the bipolar plate comprising a first surface, a second surface opposing the first surface, and a hydrophilic film grafted onto the first surface to attract water and/or spread water across the first surface of the bipolar plate.

17. The bipolar plate of claim 16, wherein the hydrophilic film has a thickness of 500 nm or less.

18. The bipolar plate of claim 17, wherein the thickness is less than 100 nm.

19. The bipolar plate of claim 16, wherein the hydrophilic film includes at least one functional group containing hydroxyl, carbon-oxygen bonds, or nitrogen-containing groups.

20. The bipolar plate of claim 16, wherein:
the hydrophilic film is a first hydrophilic film; and
the bipolar plate further comprises a second hydrophilic film grafted onto the second surface to attract water and/or spread water across the second surface of the bipolar plate.
